(19) United States
(12) Patent Application Publication
(10) Pub. No.: US 2012/0260845 A1
(43) Pub. Date: Oct. 18, 2012

(54) POLYSILICON SYSTEM

(75) Inventors: David P. Williams, Moses Lake, WA (US); Nancy Kanoff, Moses Lake, WA (US)

(73) Assignee: REC Silicon Inc

(21) Appl. No.: 13/087,256

(22) Filed: Apr. 14, 2011

(51) Int. Cl. C30B 15/14; C30B 15/20; C01B 33/02; C01B 33/021

(52) U.S. Cl. 117/13; 264/332; 423/348

(57) ABSTRACT

A polysilicon system comprises polysilicon in at least three form-factors, or shapes, providing for an enhanced loading efficiency of a mold or crucible. The system is used in processes to manufacture multi-crystalline or single crystal silicon.

### FIELD

The present disclosure relates to a polysilicon system comprising polysilicon in three form-factors, or shapes; and the use of said system to manufacture multi-crystalline or single crystal silicon.

### BACKGROUND

Silicon of ultra high purity has a variety of industrial uses including preparation of components for the photovoltaic industry or the semi-conductor electronics industry. Typically the industry will use the silicon in the form of wafers prepared from silicon ingots which can be of a mono-crystalline or multi-crystalline structure. Wafers of a mono-crystalline structure are generally preferred as they are more efficient in end application operations though more costly to prepare. Typically mono-crystalline silicon is prepared through refining of polycrystalline silicon by the Czochralski process; while a multi-crystalline silicon will be prepared by refinement using a directional solidification process. While both processes are distinctly different with respect to equipment and operations; common to both is the basic solid polycrystalline silicon starting material, which needs to be loaded and packed into crucibles or molds suitable to the respective processes. Consequently, an issue common to both is how to maximize the amount of solid polycrystalline silicon that can be loaded into the crucible or mold so as to minimize costs and maximize productivity.

Polycrystalline silicon is available in the form of rods prepared by a Siemens process and then chunks or chips obtained therefrom by the controlled fracturing or breaking rods. Of recent, polysilicon has been made available in commercial quantities in the form of essentially spherical granules due to fluidized bed production processes having been developed and implemented. The cost variable of processing to create a batch of silicon ingots is largely independent of the actual weight of the polysilicon contained in the molds. Therefore, it follows that if more polysilicon can be packed into a given mold and processed for a given amount of power, time, and labour, then the cost per kilogram of polycrystalline silicon ingot is reduced. Discussions and teachings relating to loading and packing of the molds or crucibles with polysilicon in various forms has been reported in the literature including the following publications U.S. Pat. No. 6,605,149; U.S. Pat. No. 7,141,114; U.S. Pat. No. 5,814,148; U.S. Pat. No. 6,110,272; European Patent EP 1,151,154; and Japan patent publication JP2001/010892. The loading efficiency is dependent on the form factor of the polycrystalline silicon and also on the shape and size of the mold or crucible. There is continuing desire to further enhance the loading efficiency of the molds and crucibles.

### SUMMARY

It is now observed that use of combinations of polysilicon forms and especially ternary form systems provide for a surprising and significant enhancement of the loading efficiency of the molds and crucibles as used when refining the crystallinity of polycrystalline silicon.

In a first aspect, this invention relates to a ternary-form system of polysilicon suitable for manufacture of silicon ingots which comprises as first component (Component A), polysilicon in a rod form; as second component (Component B), polysilicon in a chunk form; and as third component (Component C), polysilicon in a granule form.

In another aspect, this invention relates to a directional solidification process for production of multicrystalline silicon that comprises providing a mold suitable for melting and cooling polysilicon using a directional solidification process; loading a ternary-form system of polysilicon into the mold; and placing the mold into a furnace suitable for melting and cooling polysilicon by the directional solidification process; heating the mold until polysilicon attains a desired state of molten silicon mass; and cooling the mold thereby causing the molten silicon mass to crystallize and form a crystalline silicon ingot characterized in that the ternary-form system of polysilicon comprises as first component (Component A), polysilicon in a rod form; as second component (Component B), polysilicon in a chunk form; and as third component (Component C), polysilicon in a granule form.

In yet another aspect, this invention relates to a “Czochralski process” for the production of crystalline silicon that comprises providing a mold suitable for melting polysilicon; loading a ternary-form system of polysilicon into the mold; heating the mold until the polysilicon attains a desired state of molten silicon mass; introducing a silicon seed crystal and pulling a single silicon crystal characterized in that the ternary-form system of polysilicon comprises as first component (Component A), polysilicon in a rod form; as second component (Component B), polysilicon in a chunk form; and as third component (Component C), polysilicon in a granule form.

The foregoing and other objects, features, and advantages will become more apparent from the following detailed description.

### DETAILED DESCRIPTION

The ternary-form system disclosed herein comprises polycrystalline silicon in a combination of three form factors, or shapes. The first form factor, Component A is of rod form; the second form factor, Component B is of chunk form; and the third form factor, Component C is of, essentially spherical, granule form. Advantageously and independently, Component A is present in an amount of at least 10 weight percent, is present in an amount of not more than 80 weight percent, and is present in an amount in a range from 10 to 80 weight percent, advantageously from 10 to 60 weight percent, and more advantageously in from 30 to 50 weight percent; Component B is present in an amount of at least 10 weight percent, is present in an amount of not more than 80 weight percent, and is present in an amount in a range from 10 to 80 weight percent, advantageously from 10 to 60 weight percent, and more advantageously from 10 to 40 weight percent; and Component C is present in an amount of at least 10 weight percent, is present in an amount of not more than 80 weight percent, and is present in an amount in a range from 10 to 80 weight percent advantageously from 20 to 70 weight percent, and more advantageously from 20 to 60 weight percent based on total weight of the system; and wherein at any time or combination the sum of the percentages Components A, B and C present does not exceed 100 percent.

Component A is obtained by preparing polycrystalline silicon using the Siemens Process which in brief involves the thermal pyrolysis of a silicon-containing gas, typically monosilane or trichlorosilane, and deposition of the pyrolysis products on a filament to produce a large rod. The length and diameter of the initial rod will be dependent on the Siemens equipment but may vary from 50 to 200 mm in diameter and in length of from 500 to 2000 mm. This initial rod, depending on the size and geometry of the crucible or mold to be loaded generally to facilitate operations will be cut or machined into smaller lengths and diameters. Component A, as used herein has an average diameter of from 50 mm to 200 mm, advantageously from 40 to 140 mm; and an average length of from 100 mm to 500 mm, advantageously from 150 mm to 400 mm or less. The actual rod dimensions will be dictated by the size and geometry of the crucible or mold to be loaded.

Component B can also obtained by preparing polycrystalline silicon using the Siemens process and the so obtained large rod is then fractured and broken down into smaller chunks of irregular size and shape. For the purposes of this discussion, Component B may be characterized as random pieces of polysilicon which range from 3 mm to 200 mm across their largest dimension. The size distribution may vary, but advantageously at least 95% of the pieces will range from 10 mm to 100 mm across their largest dimension. Usually, but not always, chunk polysilicon possesses an irregular shape, and frequently has sharp, jagged edges as a result of the fact that they originate and are typically broken from a much larger rod. The sharp edges require attention when handling and may additionally cause damage to equipment. Occasionally, chunk silicon may be accompanied by the concomitant production of smaller, and irregular and sharp edged particles; such smaller material is frequently referred to a chip polysilicon. Such “chip” polysilicon may be present with the “chunk” polysilicon that represents Component B of the disclosed system.

Component C is polysilicon having a granular, spherical form factor and obtained by thermal pyrolysis of a silicon-containing gas, typically monosilane or trichlorosilane, conducted under fluidized bed conditions and in which deposition of the pyrolysis products on a silicon seed particle occurs to produce an essentially smooth spherical polycrystalline silicon granule or particle. Component C has an average diameter of from 0.1 to 20 mm, more advantageously from 0.15 mm to 15 mm, and yet more advantageously from 0.15 to 10 mm. For the most part the granulate polysilicon generally will have a mono-modal particle size distribution, though bimodal particle distribution profiles within the above ranges may offer enhanced degrees of loading and packing efficiency.

One of the primary objectives of this invention, to enhance the packing or loading efficiency of the mold or crucible, is achieved by balancing the relative proportions of the components of the ternary blend in consideration of the shape and size of the volume to be filled. Packing densities vary between various forms of polysilicon. For example, chunk polysilicon has a rather low packing density of roughly 50%. By way of comparison, chip polysilicon has a preferable packing density of roughly 57%, although this number may vary depending upon the actual size, shape and diversity of the chips. The best packing density possible for perfectly spherical objects in a given volume ranges between 74% (corresponding to the Face-Centred Cubic configuration) and 65% (corresponding to a random loose fill). However, due to the imperfect sphericity, and sometimes a porosity of granular polysilicon produced by the fluidized-bed process, granular polysilicon has demonstrated a practical packing density of roughly 60 to 65%. By “packing efficiency” it is understood that given a specific volume, such as the volume represented by the internal capacity of a mold, the polysilicon form if uniquely loaded into such a volume, on the average, would weigh roughly 50% of the weight of a solid block of polysilicon displacing the entire internal capacity of the mold.

In an advantageous embodiment, Component A is present in a range from 10 to 60 weight percent, and more advantageously from 30 to 50 weight percent. For Component B, amounts present are from 10 to 60 weight percent, more advantageously from 10 to 40 weight percent. For Component C, amounts present are from 20 to 70 weight percent and more advantageously from 20 to 60 weight percent.

In a highly advantageous embodiment, the ternary blend comprises Component A in an amount of from 30 to 50 weight percent, with Component B present in from 10 to 40 weight percent, and Component C present in from 20 to 60 weight percent; based on total weight of the system and wherein the sum of the amounts of A, B and C does not exceed 100 percent.

It is advantageous to retain a reasonable amount of Component A in the blend as this material offers advantages in the melting of the silicon prior to the preparation of the ingot. In a commensurate manner it is advantageous to use lesser amounts of Component B which because of irregular shape and edges may provoke unwanted damage to the crucible or mold; or because its method of fabrication and handling introduce unwanted metal contamination. Component C offers an ease of handling and flow hence it is to advantage to have presence in amounts typically greater than Component B.

The ternary-form polysilicon system as noted has value in the formation of single crystal silicon by pulling of crystal from a melt of the polysilicon system. This technique commonly referred to as the Czochralski process is well known to the person skilled in the art and broadly documented. In summary, it comprises loading a crucible with polysilicon; heating the crucible until melt of the polysilicon system is obtained; introducing and contacting a seed crystal with the melt; and then pulling under controlled conditions and cooling a single crystal from the melt. By single crystal, it is meant a body of silicon where it is continuous and unbroken and having no grain boundaries to its edges. In industry, such a single crystal is typically a rod or cylinder which an be up to 2 meters in length and several centimetres in diameter. Single crystal silicon is especially of value to the electronics industry for the manufacture of silicon wafers.

Similarly, the ternary-form polysilicon system has value in the formation of multicrystalline silicon ingots by directional solidification from a melt of the polysilicon system. This technique too is well known to the person skilled in the art and broadly documented. In summary, this process comprises loading of polysilicon into a mold; placing the mold into a furnace suitable for melting the polysilicon; heating the mold until polysilicon attains a desired state of molten silicon mass; and cooling the mold thereby causing the molten silicon mass to crystallize and form a crystalline silicon ingot. Typically, the ingot obtained in this manner is of multicrystalline structure and eminently useful for applications that do not demand single crystal silicon.

Given the above detailed description, examples of embodiments are presented hereinafter.

### Example 1

A standard ovoid, round bottom, 60 kg quartz Czochralski crucible of a type typically used by monocrystalline ingot manufacturers is manually filled with different blends of Siemens rod segments, Siemens chunk and FBR Granular polysilicon until the contents are level with the rim of the crucible. The form types and respective proportions are noted in Table 1 below. Loads 1-5 are comparative; Load 6 demonstrates the ternary-form system of this disclosure.
Component A is polysilicon of rod form. The rod had a diameter of approximately 100 mm and sample pieces vary in length from 100 mm to 380 mm.
Component B is polysilicon of chunk form obtained by fracturing of a polysilicon rod. Pieces are random and irregularly shaped with a size distribution of from 3 mm to 200 mm. Smaller pieces of less than 3 mm may be present, but if present in an amount of 2 wt % or less.
Component C is polysilicon of granulate form and manufactured by a fluidized bed process. The granulate is generally spherical in shape with a size distribution of particles less 0.15 mm representing less than 5 wt %; particles of from 0.15-4 mm representing at least 90 wt %; and particles of greater than 4 mm representing less 5 wt % of the overall mass.
All the above noted forms of polysilicon are available commercially from REC Silicon Inc, 3322 Road N NE, Moses Lake, Wash., USA.

Prior to the loading tests the crucible was measured: the inside diameter measured 432 mm; the interior height from the lip to the lowest point of the dome measured 342 mm; the interior height from the lip to the cylinder/dome transition measured 240 mm. The weight of the crucible, including stand, measured 21.84 kg. The volume of the crucible was verified to be approximately 44,000 cm³. Accordingly, if the crucible is filled with polysilicon at a loading or packing efficiency of 100% it should contain a theoretical weight of 102.5 kg of polysilicon

| Form Type (%) | Load 1* | Load 2* | Load 3* | Load 4* | Load 5* | Load 6 |
|---|---|---|---|---|---|---|
| Component A (Rod) | / | 51 | / | / | / | 39 |
| Component B (Chunk) | 100 | 49 | / | 58 | 50 | 24 |
| Component C (Granulate) | / | / | 100 | 42 | 50 | 37 |
| Time to fill (mins.:seconds) | 48 m 26 s | 30 m 0 s | 2 m 30 s | 37 m 2 s | 28 m 34 s | 12 m 0 s |
| Weight of contents of filled | 63.8 | 66.2 | 66.4 | 82.0 | 82.5 | 89.0 |
| crucible (kg) | | | | | | |
| Loading Efficiency % | 62.2 | 64.5 | 64.8 | 80.0 | 80.5 | 86.8 |

*Comparative Example

Use of the ternary form system of polysilicon when loading the crucible provides for a significantly enhanced loading efficiency and in a surprisingly short period of time. The ability to load greater amounts of polysilicon into a crucible for melting and ingot formation or crystal pulling represents a significant economic gain for the manufacturer as does the reduction in time to load the crucible.

In view of the many possible embodiments to which the principles of the disclosed processes may be applied, it should be recognized that the illustrated embodiments are only examples and should not be taken as limiting the scope of the invention.

We claim:

1. A ternary-form system of polysilicon suitable for manufacture of silicon ingots, which system comprises a first component (Component A) being polysilicon in a rod form; a second component (Component B) being polysilicon in a chunk form; and a third component (Component C) being polysilicon in a granule form.

2. The system of claim 1 wherein Component A is present in an amount of from 10 to 80 weight percent based on total weight of the system.

3. The system of claim 1 wherein Component B is present in an amount of from 10 to 80 weight percent based on total weight of the system.

4. The system of claim 1 wherein Component C is present in an amount of from 10 to 80 weight percent based on total weight of the system.

5. The system of claim 1 where in Component A is present in an amount of from 10 to 60 weight percent; Component B is present in an amount of from 10 to 60 weight percent; and Component C is present in an amount of from 20 to 70 weight percent; and wherein the percentage amounts of Component A, Component B and Component C as present do not exceed a total of 100 percent.

6. The system of claim 5 wherein Component A is present in an amount of from 30 to 50 weight percent; Component B is present in an amount of from 10 to 40 weight percent; and Component C is present in an amount of from 20 to 60 weight percent; and wherein the percentage amounts of Component A, Component B and Component C as present do not exceed a total of 100 percent.

7. The system of claim 1 wherein Component A, the rod-form polysilicon is initially prepared by a Siemens Process.

8. The system of claim 1 wherein Component B, the chunk-form polysilicon is initially prepared by a Siemens process.

9. The system of claim 1 wherein Component C, the granule-form polysilicon is initially prepared by a fluidized-bed process.

10. A directional solidification process for multicrystalline silicon, which process comprises providing a mold suitable for melting and cooling polysilicon using a directional solidification process; loading a ternary-form system of polysilicon into the mold; and placing the mold into a furnace suitable for melting and cooling polysilicon by the directional solidification process; heating the mold until polysilicon attains a desired state of molten silicon mass; and cooling the mold thereby causing the molten silicon mass to crystallize and form a crystalline silicon ingot characterized in that the ternary-form system of polysilicon comprises a first component (Component A) being polysilicon in a rod form; a second component (Component B) being a polysilicon in a chunk form; and a third component (Component C) being polysilicon in a granule form.

11. A Czochralski process for the production of single crystal silicon, which process comprises providing a mold suitable for melting polysilicon; loading a ternary-form system of polysilicon into the mold; heating the mold until the polysilicon attains a desired state of molten silicon mass; introducing a silicon seed crystal and pulling a single silicon crystal characterized in that the ternary-form system of polysilicon comprises a first component (Component A) being polysilicon in a rod form; a second component (Component B) being a polysilicon in a chunk form; and a third component (Component C) being polysilicon in a granule form.
